(19) United States
(12) Patent Application Publication
(10) Pub. No.: US 2009/0210178 A1
(43) Pub. Date: Aug. 20, 2009

(54) SYSTEMS AND METHODS FOR PRODUCING POWER CONSUMPTION DATA

(76) Inventor: Paul Bieganski, Orono, MN (US)

Correspondence Address: SCHWEGMAN, LUNDBERG & WOESSNER, P.A., P.O. BOX 2938, MINNEAPOLIS, MN, 55402, US

(21) Appl. No.: 12/032,383

(22) Filed: Feb. 15, 2008

(51) Int. Cl. G01R 21/00

(52) U.S. Cl. 702/62; 324/142

(57) ABSTRACT

Systems and methods for producing power consumption data enabling up-to-the-minute automatic collection and transmission of real-time energy flow information are described. Energy consumption from a source of electricity by an electrical device may be measured. This measured data may then be stored for later transmission on a wireless network. Additionally, energy consumption data from another measurement device may be received and stored or retransmitted until it reaches a gateway where it is harvested. The harvested data may be stored and organized for display to a user. Embodiments may allow for a low-cost high precision integrated power meter IC in combination with a low-cost radio transceiver chip to control part count and cost of power monitoring node implementation to provide for internet-based power monitoring, management and analysis at any level of granularity. Other embodiments are described and claimed.

### RELATED APPLICATIONS

This application is related to U.S. application titled “SYSTEMS AND METHODS FOR POWER CONSUMPTION DATA NETWORKS” (Attorney Docket No. 2728.001US1) filed on even date herewith.

### BACKGROUND

Increases in energy prices, combined with heightened geopolitical and environmental concerns have resulted in greater interest in energy efficiency. In a pattern consistent with past energy crises, the initial wave of interest has focused on the supply side of the issue, including alternative energy sources (PV, wind, biofuels etc.). With the limitations (including high or extremely high capital costs and established supply chains) of augmenting or disrupting the supply-side becoming apparent, focus should shift to the more easily achievable and more capital efficient demand side through increased efficiency and better utilization of existing resources.

The electrical power distribution system can be extremely inefficient and wasteful, operating in some circumstances as a “use-it-or-lose-it” system of distributing electrons. Some have made progress through better management of peak loads using techniques including: “demand management”, “peak shaving” etc.

The world of electricity consumption is remarkably blind when it comes to answering questions regarding most energy use. Most systems operate on the basis of total energy used (i.e. the basic, building or circuit level energy meter).

### BRIEF DESCRIPTION OF THE DRAWINGS

Embodiments of inventive subject matter may be best understood by referring to the following description and accompanying drawings, which illustrate such embodiments. In the drawings:

FIG. 1 is a block diagram of a system for collecting and communicating power consumption data according to various example embodiments;

FIG. 2 is a more detailed block diagram of a remote device for collecting and communicating power consumption data according to various example embodiments;

FIGS. 3A and 3B are flow diagrams illustrating a method for collecting and communicating power consumption data according to various example embodiments;

FIG. 4 is a flow diagram illustrating a method for collecting and communicating power consumption data within a mapped network topology according to some example embodiments;

FIG. 5 is a block diagram of an example system for collecting and communicating power consumption data according to one example embodiment of the present invention;

FIG. 6 is a graphical representation of a computer interface for monitoring remote devices according to an example embodiment;

FIG. 7 is a graphical representation of a computer interface for monitoring power consumption according to an example embodiment; and

FIG. 8 is a block diagram of a computer system that executes programming according to various example embodiments.

### DETAILED DESCRIPTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that structural, logical and electrical changes may be made without departing from the scope of the present invention. The following description of example embodiments is, therefore, not to be taken in a limited sense, and the scope of the present invention is defined by the appended claims.

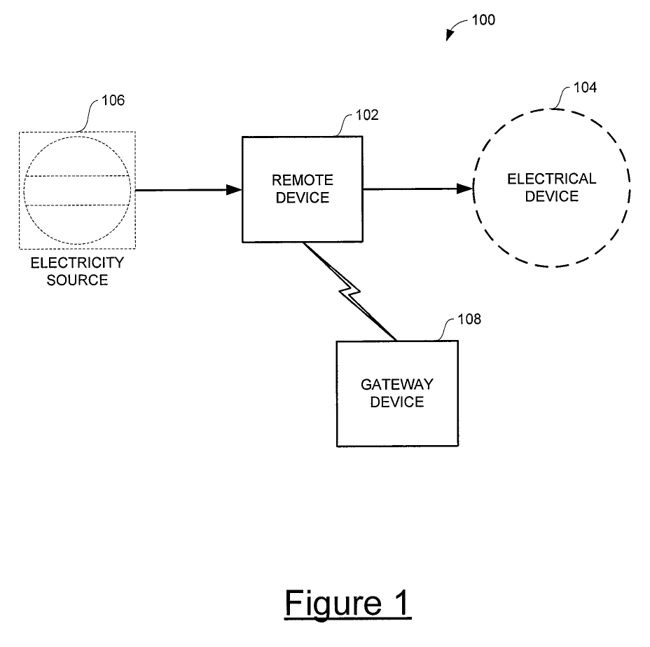

FIG. 1 is a block diagram of a system 100 for collecting and communicating power consumption data according to various embodiments. The system 100 includes, a remote device 102 in communication with an electrical device 104, an electricity source 106, and a gateway device 108.

An electrical device 104 monitored by the system 100 may include any device such as servers, network switches, refrigerators, home consumer appliances, electricity-generating solar panels or other electricity consuming or generating device. In operation, the electrical device 104 may draw power from an electricity source 106. The remote device 102 is a measurement device and may be connected between the electrical device 104 and the electricity source 106 or integrated with the electrical device 104, allowing electricity to flow from the electrical source 106 to the electrical device 104. According to some embodiments, the remote device 102 may include male and female AC power plugs to interface with the electricity source 106 and electrical device 104 respectively. In other embodiments, the remote device 102 is integrated into the electrical device 104 and is connected to a cord or connector to connect with the electricity source 106. In yet another embodiment, the remote device 102 may integrated or retrofitted into a power cable designed to plug into the electrical device 104 and the electricity source 106. This setup would allow for fewer connections and fewer points of failure. Multiple remote devices 102 may additionally be integrated into a power strip for use with multiple electrical devices 104. The remote device 102 itself may be powered by the electricity source, or may receive power from another source such as a battery or auxiliary power source.

The remote device 102 may operate to monitor the flow of electricity from the electricity source 106 to the electrical device 104. This monitored electricity flow data may be initially stored in a memory in the remote device 102. In other embodiments, the electricity flow data may be transmitted wirelessly or otherwise from the remote device 102 to a gateway device 108. According to some embodiments, the electricity flow data may be transmitted over radio frequencies over airwaves, over a wire-line network (e.g. Ethernet), over a fiber-optic network, over a power-line network, or other networks medium. The remote device 102 may combine the electricity flow data with temporal data for storage or transmission. Other data may also be gathered by the remote device. This additional data may include temperature, humidity, sound level, motion, light, or other data. Stored electricity flow data and any accompanying data may be transmitted instantly, periodically, at times defined by storage thresholds (e.g. when the memory is full or near full), randomly, or based on some other scheduling or triggering.

The transmission may be received by a gateway device 108 and stored either at the gateway device 108 or at a data store in communication with the gateway device 108. This data may be available for users to monitor and analyze energy use with respect to time or other measured characteristics.

According to some embodiments, the electricity source 106 may be building or room specific, and may simply be a wall socket, a space on a power strip, a breaker connection, or other similar electric source outlets. According to other embodiments, the electricity source 106 may represent a larger scale source of electricity, such as a power plant. Multiple electricity sources 106 may represent varying types of electricity resources (e.g. nuclear plant, coal plant, photovoltaic arrays, wind turbines/fields, hydro-electric plants, fuel cells, and others). Monitoring and packetizing the data regarding electricity use based on the source of the electricity may allow for control of electricity flow from selected resources. Additionally, prioritization of electricity use from various sources/resources is also contemplated.

A remote device 102 may not only have the functionality to measure and transmit energy usage data, but the remote device 102 or some other device may be operable to regulate the flow of electricity from the electricity source 106 to the electrical device 104. In some embodiments, multiple electricity sources 106 may be connected to an electrical device 104. Multiple remote devices 102 may operate to measure and control the energy flow from each of the electricity sources 106 to the electrical device 104.

According to some embodiments, the remote device 102 may include a visual indicator to indicate operational status, electricity flow or consumption or other characteristics. The visual indicator may be a light with changing intensity or color in patterns to indicate some status or power flow/consumption information. In some embodiments, the remote device 102 may include a substantially translucent enclosure with the lighting within. In other embodiments, the one or more lighted indicators may be used.

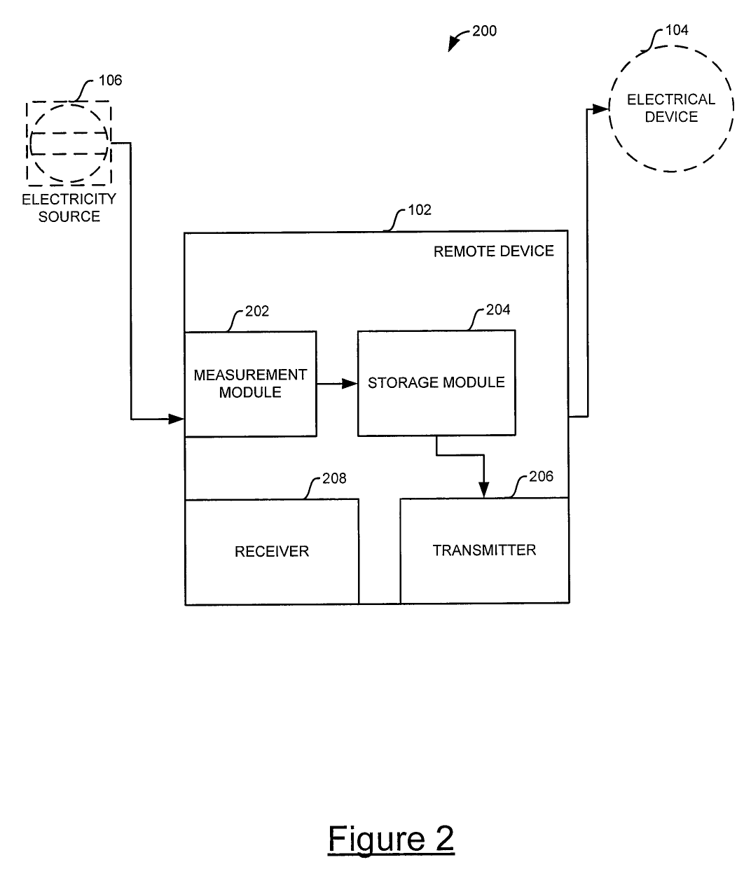

FIG. 2 is a more detailed block diagram of a system 200 including a remote device 102 for collecting and communicating power consumption data according to various embodiments. The system 200 includes the remote device 102, the electrical device 104, and the electricity source 106. The remote device 102 according to this embodiment includes a measurement module 202, a storage module 204, a transmitter 206, and a receiver 208.

As described above with reference to FIG. 1, the remote device 102 is connected between an electrical device 104 and an electricity source 106. The remote device 102 may collect electricity flow data which is representative of energy usage, and may be referred to herein as energy usage data or power consumption data. As electricity flows through the remote device 102 from the electricity source 106 to the electrical device 104, the measurement module 202 may monitor the electricity flow to generate energy usage data. The energy usage data may be stored in the storage module 204. The energy usage data stored in the storage module 204 may include energy data measured in Watt-hours (“Wh”) or some equivalent (i.e. Joules). The measurement module 202 may create the energy usage data by integrating energy over time, where the energy is measured as voltage times current (V*I). Measured in volts and amps, the product is a power measurement in Watts, although the inventive subject matter is not limited to any particular unitary system. The energy data may be stored as energy usage data with the addition of temporal information such as a time stamp. In this way, usage over time may be easily determined by simply subtracting an earlier recorded energy usage datapoint from a later energy usage datapoint. The energy usage data may be combined with other measured data which may include quality data (number of spikes or over-voltages, number of sags or under-voltages, average voltage, average current, peak voltage & current, peak power, bottom power), or other measured characteristics such as temperature, humidity, sound level, motion, light, or others.

After an amount of time has passed or an amount of data has been collected, the stored energy usage data in the storage module may be sent to the transmitter 206 to be broadcast wirelessly. The broadcast transmission may include at least a portion of the stored energy usage data, including any temporal data or other measured data, and an identifier. The remote device may have a pre-determined identifier, or an identifier may be created for the remote device during installation, during operation or at another time. In accordance with some embodiments, measured energy usage data may be stored by the remote device 102 in the storage module 204, and this data may be appended in a number of ways. Newly measured data may be appended to previously stored data in order to support certain frequencies of transmission or temporal resolutions of the data, or a combination of both. Current cumulative data is generally stored prior to transmission according to several embodiments. Storage and accumulation of data can make the system robust with respect to a connection loss. In this way, after a connection is lost, when the connection is re-established, the cumulative stored data may be transmitted, allowing for substantially complete and accurate results to be kept. The amount of past data stored may vary, but will generally allow a way to increase resolution with enhanced communication channel quality or reliability. In some embodiments, the data stored in the storage module 204 is stored in a single file, and newly measured data is merged into the single file. In other embodiments, multiple files are used. The multiple files may be multiple files of distinct stored data, or may be multiple versions of a particular file. Using multiple versions may provide redundancy and protect against data corruption, similar to a backup scheme.

Additionally, the remote device 102 may be configured for a particular reporting regime. The remote device 102 may store energy use data in the storage module 204 at certain intervals, and that data may be transmitted by the transmitter 206 according to another interval. The intervals may be adjusted to reflect the temporal data reporting needs of a user. For example, substantially real-time reporting may be needed wherein the transmission interval may be set to shorter time periods (e.g. every minute) to provide increased granularity of updated data.

According to various embodiments, the remote device 102 may include a receiver 208 to receive incoming broadcast transmissions. The remote device 102 may receive transmissions from other remote devices or from gateway devices. The received data may include energy usage data, network topology data or other data. Once data is received at the receiver 208, the received data may be stored in the storage module 204 or sent directly to the transmitter 206 for retransmission. If stored in the storage module 204, the received data may be transmitted after an amount of time has passed or an amount of data has been collected. The transmission may include the received data and energy usage data collected by the measurement module 202, or the received data and the collected energy usage data may be transmitted separately by the transmitter 208.

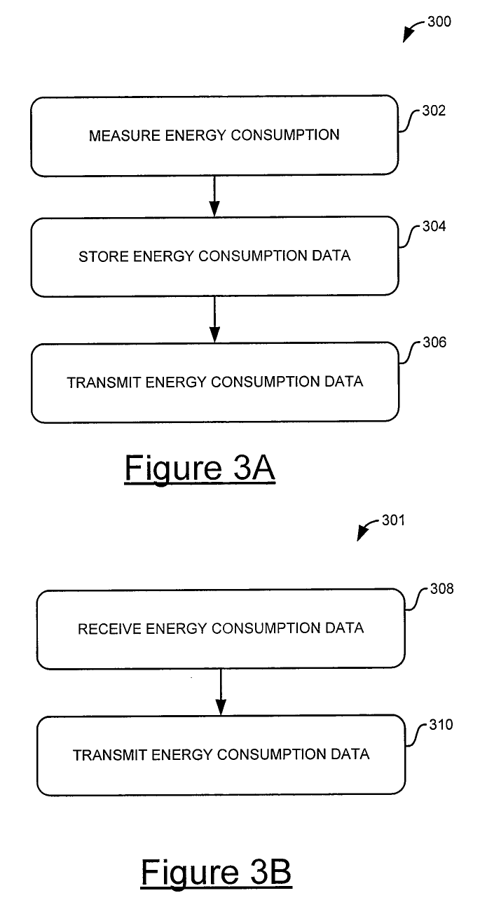

The embodiment of FIG. 3A illustrates a method 300 for collecting and communicating energy consumption or generation data. The method includes measuring energy consumption 302, storing energy consumption data 304, and transmitting energy consumption data 306.

The method 300 starts by measuring energy consumption (block 302). The measurement may be performed by a remote device connected inline between an energy source and a device using the energy. The energy consumption data may include temporal data to indicate energy use over time. The measurements may be made substantially continuously, on a periodic basis, or based upon some other interval. The measurements may be made regardless of the amount of energy being consumed, or measurements may only be made after energy consumption is greater than a threshold value.

Once the energy consumption is measured, the energy consumption data may be stored on the remote device (block 304). Subsequent measurements may also be added to the storage. After an amount of time has passed, a scheduled time slot has arrived, or an amount of data has been stored, the stored energy consumption data on the remote device may be transmitted (block 306). The transmission may be a broadcast radio transmission. The energy consumption data may also include identification data related to the remote device. In a system which includes multiple remote devices, each remote device may have a different identifier in order to help identify the source of the energy consumption data. According to various embodiments, the identifier may be printed on the casing of each remote device. The identifier may be printed as a series of numbers or it may be represented as a barcode or other optically readable or computer readable (including RFID) means to identify a remote device.

The embodiment of FIG. 3B illustrates a method 301 for collecting and communicating energy consumption or generation data. Separately or in conjunction with the method 300 described with reference to FIG. 3A, another method 301 allows for energy consumption data to be received (block 308) and further transmitted (block 310). The remote device may be operable to receive incoming transmissions which include energy consumption data (block 308). Received energy consumption data may be optionally stored with existing energy consumption data on the device or may be retransmitted (block 310) without storage. If stored with existing energy consumption data, the received energy consumption data and the existing energy consumption data may be transmitted (block 310) at some point after an amount of time has passed or an amount of data has been stored.

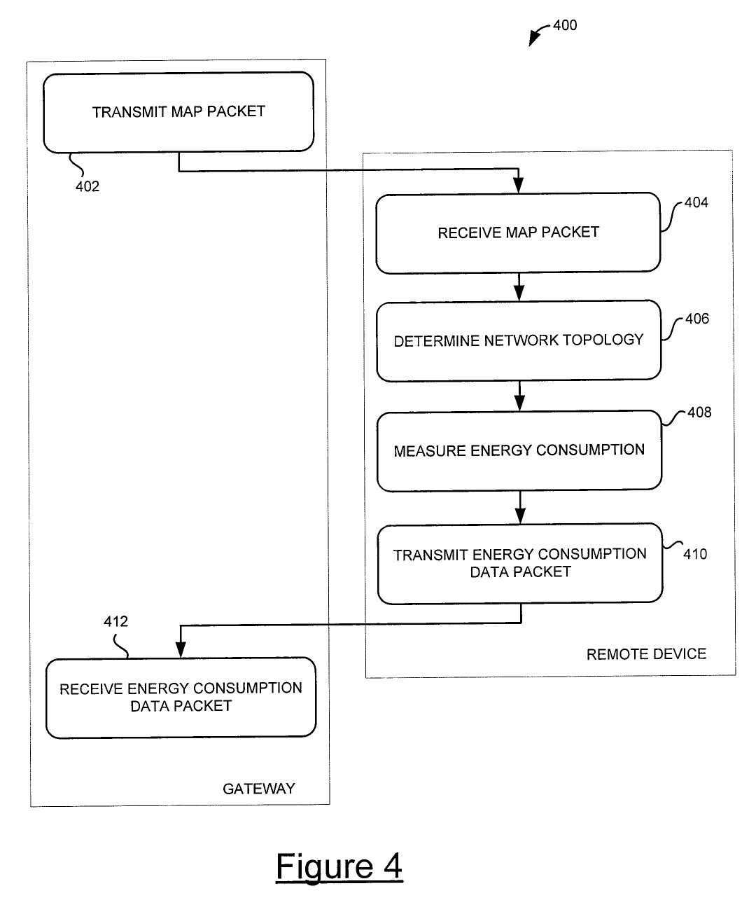

The embodiment of FIG. 4 illustrates a method 400 for collecting and communicating energy flow data within a mapped network topology. The method 400 includes at least two major phases, a mapping phase and a harvest phase. The mapping phase includes transmitting (block 402) and receiving (block 404) a map packet, as well as determining network topology based on the packet data (block 406). The harvest phase includes measuring energy consumption (block 408), and transmitting (block 410) and receiving (block 412) the associated energy consumption data.

The method 400 represents an operational cycle and begins in the mapping phase with a gateway device initially transmitting a map packet (block 402). The mapped packet is used to provide remote devices with information regarding its relative topological position and connectivity within the network to maximize the probability of reliable data transmission. The map packet information may include one or more of a packet type indicator, a cycle ID, a cycle length, phase length a phase number of the current phase, a phase clock, a hops count, and other information. The transmitted map packet may be received by a the remote device (block 404). The remote device may use the map packet to help determine a network topology. Upon receiving a map packet, a remote device may pick a time slot (mapSlot) in the remaining operational cycle length (i.e. some time between current time and operational cycle length). Upon receiving subsequent map packets the remote device may keep track of the distance from a gateway device that each map packet has traveled. That distance information may be recorded and the lowest distance (hopsFromMaster) packet(s) may be noted. The remote device also can keep track of the number of map packets received from other remote devices at the shortest observed hop distance. This approximates the number of topologically near remote devices exist at substantially the same distance. These remote devices may be referred to as “neighbors.” When a particular mapSlot time arrives for a remote device, the remote device can re-transmits a map packet, with appropriate distance data equal to the lowest hop distance observed, plus one. Considering the importance of timing, clock times for each remote device and gateway devices may be synchronized during the mapping phase using the map packets.

During the mapping phase, transmitted and received map packets may query remote devices in order to determine additional network topology information. Gateway devices may query for various estimated remote device-level protocol variables such as estimated distance, neighborhood size, and other characteristics. These estimated characteristics may be gathered for the purposes of discovering additional detail regarding the topology of the network.

The harvest phase may begin after the mapping phase and network topology determination. Multiple harvest phases may follow a mapping phase. A remote device may begin by measuring energy consumption of an electrical device (block 408). This energy usage data may be stored and transmitted or simply transmitted (block 410). The intended destination of the energy usage data may be a gateway device, however, the transmitted energy usage data may be received and retransmitted by one or more remote devices on its way to a gateway device. Eventually, the energy usage data may be received by a gateway device (block 412). The received/transmitted energy usage data may be sent within a data packet and may include one or more of a packet type indicator, a cycle ID, a cycle length, phase length a phase number of the current phase, a phase clock, measurement data, a hops remaining count, and other information. The included measurement data may include recently measured data, such as data measured since the last transmission, in addition to past stored data. By including past stored data, the likelihood that all of the data reaches a gateway device and data store for presentation to a user is increased. Graceful degradation is provided for the stored and transmitted data in case of communication losses.

In an example embodiment, at the beginning of the harvest phase a remote device may pick a time slot (harvestSlot) during which it transmits its data (i.e. its energy usage data). At all other times during the harvest phase the remote device may listen for incoming broadcast transmissions. When a remote device receives an incoming data packet, it may check the data packet for remaining lifetime (hopsRemaining). The lifetime of a data packet may be defined as a threshold number of hops between remote devices before the packet is discarded. If the data packet has lifetime remaining equal to the estimated distance of the receiving remote device from a gateway device (a distance which is estimated during the mapping phase), it forwards the packet immediately (in the next time slot harvestSlot). The transmission probability may be inversely proportional to the size of the neighborhood of the remote device (as estimated during the mapping phase). For example, a remote device with an estimated neighborhood size of 1 and a distance of 3 hops from a gateway device will forward a packet with hopsRemaining=3 with 100% probability. Another remote device with estimated neighborhood size of 3 at a distance of 2 hops from a gateway device will forward a packet with hopsRemaining 2 with 33% probability. The same remote device would ignore all packets with hopsRemaining below 2.

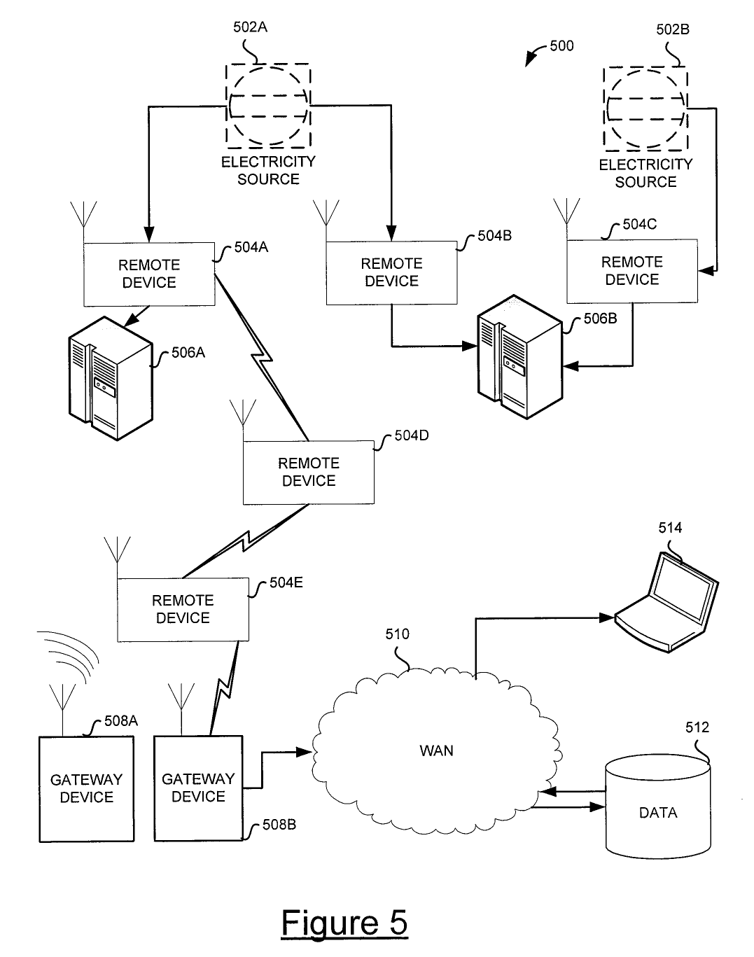

FIG. 5 is a block diagram of an example system 500 for collecting and communicating power consumption data according to one embodiment of the present invention. The system 500 includes electricity sources 502A, 502B, remote devices 504A, 504B, 504C, 504D and 504E, appliances 506A and 506B, gateway devices 508A and 508B, a wide area network (WAN) 510, a data store 510 and a networked personal computer (PC) 514.

The remote devices 504A-E may be connected between an appliance 506A-B and an electricity source 502A-B according to various embodiments. In other embodiments, one or more remote devices 504A-E may be integrated components of one or more appliances 506A-B. As described above, the remote devices 504A-E may measure and store as data the power consumption of the appliances 506A-B from the electricity source 502A-B to which they are attached. The appliances 506A-B may be any number of electrical devices. The remote devices may broadcast data gathered regarding energy consumption over radio frequencies. Other remote devices 504A-E or to gateway devices 508A-B may receive the broadcast data. Remote devices 504A-E may retransmit the received data in order to advance the data toward a gateway device 508A-B. Once received by the gateway device 508A-B, the energy consumption data may be communicated over wide area network (WAN) 510 to a data store 512. The wide area network may be a private network or public network such as the internet. The data store 512 may receive incoming data over the WAN 510 and is operable to store that data and organize it in a number of ways. The data store 512 may include or be in communication with a server which may be operable to serve the stored data in for access and viewing. A user on a PC 514 connected to the WAN 510 may access the data stored in the data store 512. Access of the data stored in the data store 512 may be done through a number of interfaces including raw data access, web based access, or others.

According to various embodiments, multiple remote devices 504A-B may be used to monitor energy consumption from the same electricity source 502A, supplying different appliances 506A and 506B. According to other embodiments, a single appliance 506B may have multiple electricity sources 502A and 502B. The energy consumption from each electricity source 502A-B may be monitored separately by separate remote devices 504B-C. Additionally, remote devices 504A-E may be set up in series, for example, where one remote device 504A-E is connected between a electricity source 502A-B and a power strip, and a second remote device 504A-E is connected between the power strip and an appliance 506A-B. In the case of remote devices 504A-E connected in series, their tree type topology configuration may be automatically detected and accounted for in data collection and analysis either at the remote device 504A-E, at the data store 512, or at the PC 514. This detection allows for the same energy usage to not be double counted or double reported. The system 500 may determine the electrical network topology and avoid double-counting by correlating current, voltage and power usage variances as well as quality disturbances (sags, spikes/over-voltages) over time between remote devices 504A-E. Identifiers associated with each remote device 504A-E may be used to differentiate remote devices and define the electricity source-appliance combination. In this way, automatic detection of the topology of the electrical network may be performed by the remote devices 504A-E, and that data may be transmitted through the gateway devices 508A-B to the data store 512 to be displayed to a user on some device or PC 514.

Detecting and determining the electrical network topology allows for understanding of what is plugged into what, and not just what appliance 506A-B is powered by what electricity source 502A-B. Understanding the particular series or parallel relationships between the remote devices 504A-B can avoid issues like double recording of energy usage which could lead to double-billing. Electrical network topology information may also allow for automatic determination of any potential redundancy or separation issues (e.g. certain critical devices/appliances connected to the same circuit). In case of devices with uneven loads (e.g. electrical motors in compressors that have high peak consumption during startup) electrical network topology information can be used to detect the fact that multiple such devices (e.g. two motors) on the same circuit could cause an overload condition if both were to initiate startup at the same time, potentially tripping a breaker (or worse). Detecting the electrical network topology and correlating electrical characteristics (current, voltage and power usage variances as well as quality disturbances) over time and produce data that can be used to predict/highlight potential failure risks. This analysis may be then utilized in making topology arrangement decisions or modifying the topology. With additional controls, this electrical network topology information may be used intelligently to delay the start of one appliance 506A-B if another one is drawing peak power. According to other embodiments, appliances 506A-B can be pre-allocated non-overlapping time slots during which they are allowed to start up. This may allow for a power network to can run at higher overall utilization. Lower capacity distribution networking (wiring) may be able to be used because remote devices 504A-E can coordinate their energy usage to avoid generating excessive temporary peak loads. Embodiments like the one just described may be implemented at a single location (e.g. a facility, data center, office, house, or others) and may allow for lower installation cost for wiring (by controlling and lowering the peak power rating) and reliability savings (decreasing or eliminating overloads).

According to an embodiment, a simple implementation of electrical network topology discovery and control can allow a user to have two big appliances 506A-B which may have high startup current installed in a house (e.g. a washer and an Air Conditioning “A/C” unit). By synchronizing the behavior of the appliances 506A-B to never initiate a startup sequence at the same time, peak power loads can be successfully controlled and limited. As an example, an A/C unit could be set to only be allowed to start on even seconds of the clock and a washer could be set to start only on the odd seconds. With example startup peaks lasting only a few hundred milliseconds such an implementation can actually be sufficient to prevent tripping a breaker in a situation where both appliances happen to start at the approximately same time.

As an electrical network topology gets more complex, power control solutions become less trivial. The system 500 may combine the electrical network topology information with actual power consumption behavior to allow for increased control over the appliances 506A-B and their energy use in time. Since the electrical network topology and power consumption information are based on observed characteristics and behavior, specific information about an appliance 5-6A-B is not necessary to allow the system 500 to function and provide power analysis and control.

In accordance with some embodiments, the system 500 may implement its processes an communications by include cryptographic signing of some or all data used and transmitted. Remote devices 504A-E may include unique node keys with their data transmissions. Gateway devices may include unique node keys with received transmissions. Other cryptographic signing may come in the form of system operator keys, billing entity keys, customer keys, and other keys assigned to various levels of interaction with the system 500 as a whole.

In one embodiment, a remote device 504A monitoring the energy consumption by an appliance 506A of an electricity source 502A may packetize the energy usage data for transmission. Once broadcast, the energy usage data may be directly received by a gateway device 508A-B. Another remote device 504D may receive the transmitted energy usage data and may retransmit that data. Other remote devices 504E may receive the retransmitted or subsequently retransmitted energy usage data as well. Once received by a remote device 504E which is within transmission range of a gateway device 508B, the energy usage data may be transmitted to the gateway device 508B. The path of reception and transmission among the remote devices 504A-E may not be the same from one transmission to the next, and the addition or subtraction of remote devices 504A-E generally should not affect the ability of a transmission of energy usage data to get to a gateway device 508A-B. In some embodiments, the radio links between the remote devices 504A-E may be assumed to be unreliable and to have limited range. The ability to communicate with every remote device 504A-E or gateway device 508A-B may not directly exist and generally is not be expected to directly exist. Some connection, however, to every remote device in a particular area or network (assuming an unlimited number of intermediate hops) is generally assumed to exist. Every remote device 504A-E is assumed to be able to communicate with at least one other remote device 504A-E or gateway device 508A-B in each direction (to and from). The “to” and “from” communication does not have to be with the same remote device 504A-E or gateway device 508A-B. All communication may be broadcast communication (i.e. any remote device 504A-E or gateway device 508A-B can potentially receive any transmission). In that way, any gateway device 508A-B may receive a transmission from any remote device 504A-E. Regardless of which gateway device receives an energy usage transmission, that data will get communicated over the WAN 510 to the data store 512.

Communication with and between remote devices 504A-E and gateway devices 508A-B may employ a number of possible transmission types or characteristics. In some embodiments, remote devices 504A-E may use frequency hopping based on a pseudo-random sequence with a common key (e.g. the phase clock) for energy usage data transmission. The remote devices 504A-E may also support dynamic subdivision of the population of remote devices 504A-E and gateway devices 508A-B. In some example embodiments, different subsets of remote devices 504A-E can operate parallel on disparate frequency sets or non-conflicting pseudo-random frequency sequences.

According to various embodiments, a remote device 504A-E may be designed to run with very limited power consumption to not substantially affect the energy usage data with its own electricity consumption. An example remote unit 504A-E may include an 8 bit CPU with 16k ROM and as little as 256 bytes of RAM. This low profile may cut back on energy consumption and also manufacturing costs associated with the remote unit 504A-E. Each remote unit may also be uniquely pre-identified and given a identifier before it is even placed in use. The pre-identification allows for configuration-free installation of remote devices 504A-E in their operating environment. The identifier may then be used to identify a particular electricity source 502A-B, appliance 506A-B combination.

In an example embodiment, the collected data stored in the data store 512 may be made available to users on a PC 514 via an internet connection using a web based interface. A dashboard may be provided to manage and analyze collected data. Depending on the intended use of the energy usage data, billing and configuration functions may be available through the web interface. The information may be provided and maintained in the proper context based on association of the remote device 504A-E identifiers, and temporal data associated with the energy usage. Information can be tied to customers or groups of customers or specific locations based on the data. Information may even be overlaid on top of facility data, providing rich energy and environmental maps. Since the energy usage data may include accurate records of energy consumption, with up to the second granularity or better, the gathered information may be useful for billing purposes in example embodiments. Variable rate billing may be employed based on time and consumption data. Different rates for electricity consumption may be used for different times of the day, or days of the week, or months or seasons of the year, etc. Varying rates may also be applied for varying amounts of electricity consumption as well. With power-meter quality data, utility billing level and certified accuracy is an option as well.

Without detailed, device-level information a data center operator may not in many cases understand the true economics of their own business and cannot optimally price their services. The system 500 may provide utility billing-quality, real-time power flow measurement enabling detailed usage monitoring, analysis, billing and optimization. As energy usage data is processed after passing through a gateway device 508A-B, either at the data store 512 or at another server, the energy usage data may be augmented with rate data (price per Wh at any given time) which may be static or variable. This rate data augmentation allows for the generation of dollar amounts used during a given time period. In combination with authentication of remote devices 504A-E, this allows for the ability to bill for selective services (e.g. a specific set of servers or a refrigerator or other select appliances) rather than just for total power use. The remote devices 504A-E may also measure environmental information and other power information including power quality, temperature, lighting and noise.

The example embodiment described with reference to FIG. 5 uses a wireless protocol to transmit and communicate energy usage and other data between the remote devices 504A-E and gateway devices 508A-B and ultimately the data store 512 and PC 514. The inventive subject matter, however, should not be read to be limited to wireless applications. The transfer of energy usage data from the remote devices 504A-E may take place over a typical wired network (e.g. Ethernet), an optical network (e.g. fiber optic), or a power-line network.

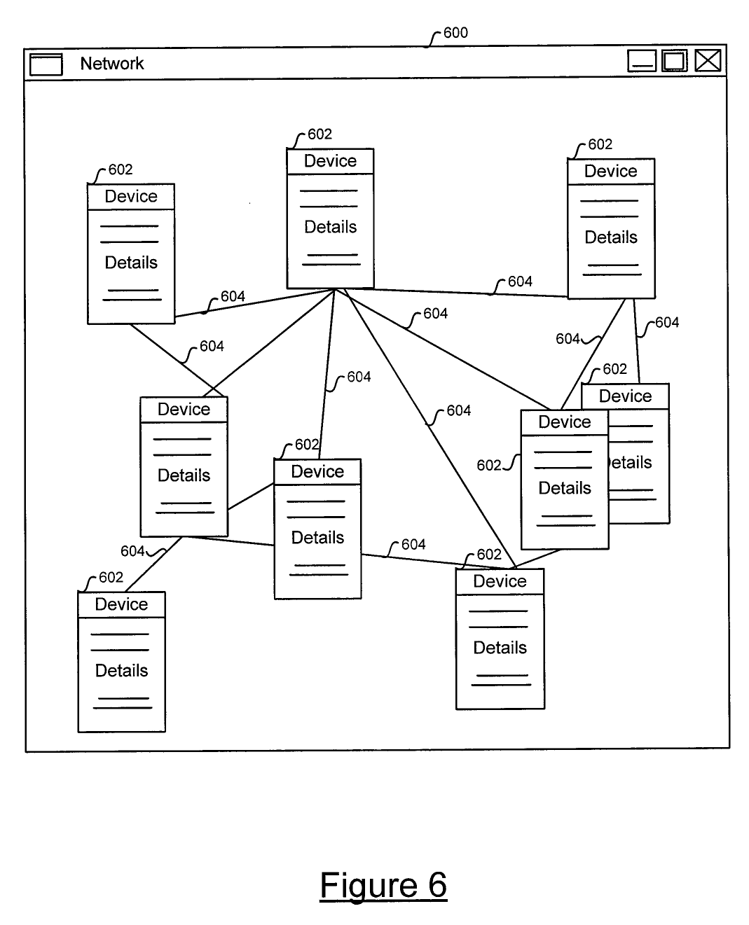

FIG. 6 is a graphical representation of a computer interface 600 for monitoring remote devices according to an example embodiment. The computer interface 600 may be a graphical user interface (GUI) that may include remote node representations 602 and connection representations 604. The remote node representations 602 may represent remote devices or gateway devices according to various examples. The remote node representations 602 may include data identifying each remote device or gateway device, along with other information regarding operation or characteristics of the remote device or gateway device.

The connection representations 604 may be lines or links connecting the remote node representations 602. The connection representations 604 may represent actual successful wireless broadcast and reception between one remote node and another.

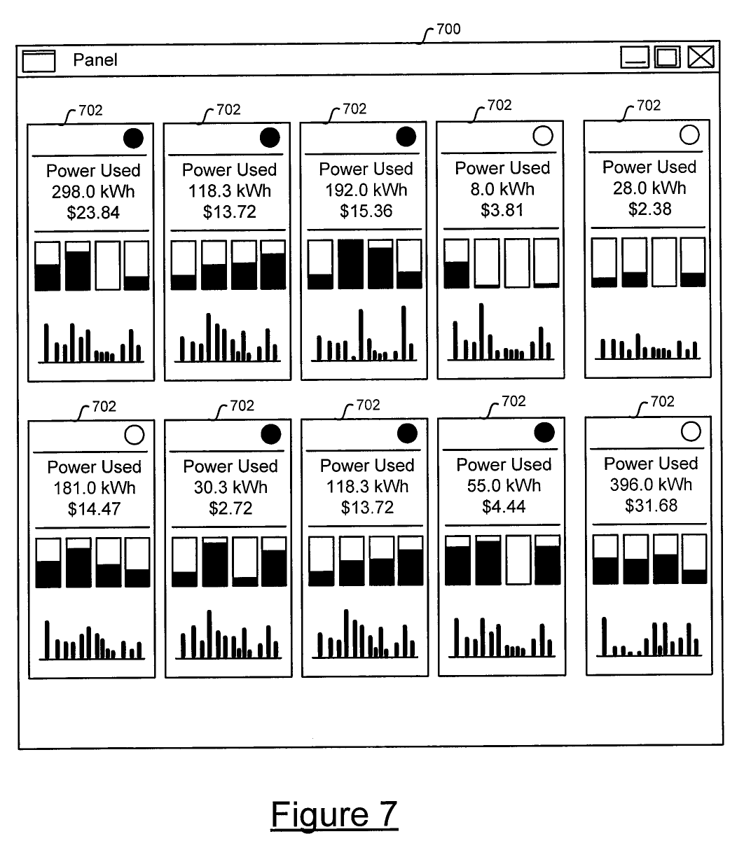

FIG. 7 is a graphical representation of a computer interface 700 for monitoring power consumption according to an example embodiment. The computer interface may be a GUI that may include one or more remote device monitors 702. The remote device monitors 702 may display periodically updated, real time, or historical data received from remote devices monitoring power consumption. The remote device monitors 702 may include a number of indicators, alphanumeric displays and charts. Indicators may include operational status, power consumption activity, data transmission activity, or other indicators. Alphanumeric data may include device identification, power usage numbers, cost numbers associated with the power usage, power usage rates, current, voltage, or power measurements, or other data. The charts may include power usage trends, cost trends, power, voltage, current, or temperature status, or other graphical data. The computer interface 700 may include other data with respect to gate way devices as well. The gateway device data may include bandwidth, number of connections, throughput, and other data related to communication with the remote devices.

With reference to FIGS. 6 and 7, within a computer interface 600 or 700 for monitoring power consumption, additional data may be collected, stored or archived for viewing in a graphical format or in a raw data format. The raw data format mat be presented as one or more tables. A user may have the ability to manipulate the orientation or sorting of the data to view the data in a number of ways for various types of analysis of power consumption and electrical device operation.

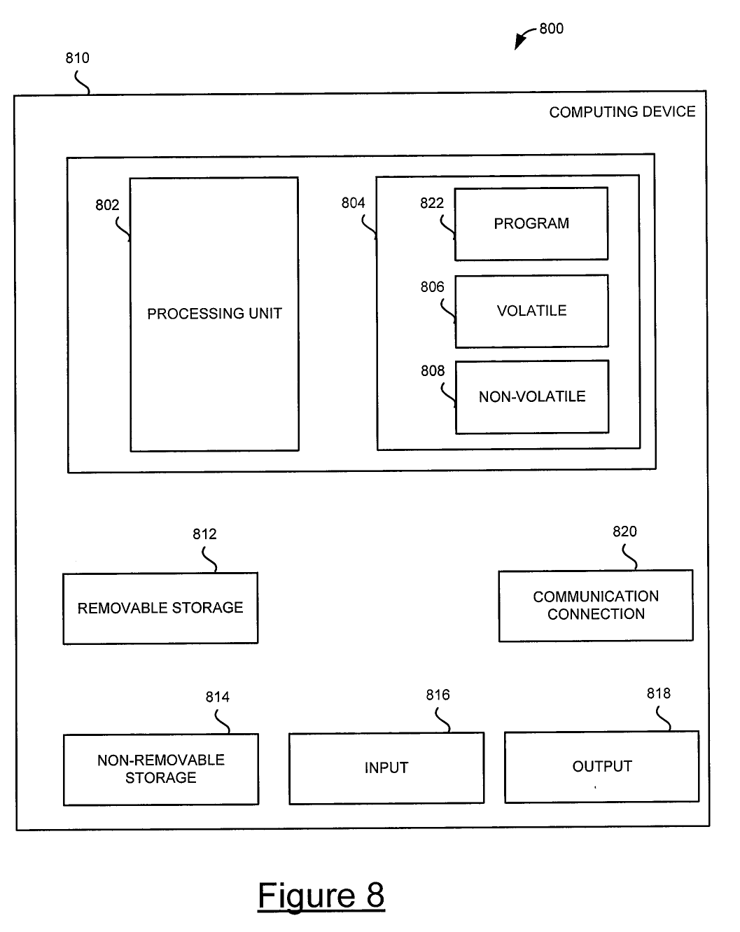

FIG. 8 illustrates an embodiment of a computer system 800 that executes programming. A general computing device 810, may include a processing unit 802, memory 804, removable storage 812, and non-removable storage 814. Computer-readable instructions stored on a computer-readable medium are executable by the processing unit 802 of the computing device 810. A hard drive, CD-ROM, and RAM are some examples of articles including a computer-readable medium. Instructions for implementing any of the above described methods and processes may be stored on any of the computer readable media for execution by the processing unit 802. The memory 804 may include volatile memory 806 and/or non-volatile memory 808. Additionally, the memory 804 may include program data 822 which may be used in the execution of various processes. Storage for the computing device may include random access memory (RAM), read only memory (ROM), erasable programmable read-only memory (EPROM) & electrically erasable programmable read-only memory (EEPROM), flash memory, one or more registers, or other memory technologies, compact disc read-only memory (CD ROM), Digital Versatile Disks (DVD) or other optical disk storage, magnetic cassettes, magnetic tape, magnetic disk storage or other magnetic storage devices, or any other medium capable of storing computer-readable instructions.

The computing device 810 may include or have access to a computing environment that may include an input 816, an output 818, and a communication connection 820. The computing device 810 may operate in a networked environment using a communication connection to connect to one or more remote computing devices. The remote computing device may include a personal computer (PC), server, router, network PC, a peer device or other common network node, or the like. The communication connection may include a Local Area Network (LAN), a Wide Area Network (WAN) or other networks. In some embodiments, the computing device 810 may reside on one or more remote devices for measuring and transmitting energy consumption data. In other embodiments, the computing device 810 may reside on one or more gateway devices. In further embodiments, the computing device 810 may reside on other devices, which communicate with a gateway or remote device.

The Abstract is provided to comply with 37 C.F.R. §1.72(b) to allow the reader to quickly ascertain the nature and gist of the technical disclosure. The Abstract is submitted with the understanding that it will not be used to interpret or limit the scope or meaning of the claims.

What is claimed is:

1. A method comprising:
measuring energy consumed by a first electrical device from a first energy source;
recording temporal data associated with the measured energy consumed;
storing the measured energy consumed and temporal data as a first energy data item;
appending the first energy data item with additional measurements of energy consumed by a first electrical device from a first energy source and associated temporal data;
associating a first identifier with the first energy data item, the identifier to identify the first electrical device and the first energy source; and
transmitting the energy data item and associated identifier.

2. The method of claim 1, wherein the identification is at least one of the following: a static identification, a predetermined identification, a randomly generated identification, or a configurable identification.

3. The method of claim 1, further comprising measuring an additional characteristic to create additional data to be stored with the energy data item.

4. The method of claim 3, wherein the additional characteristic includes at least one of the following: temperature, humidity, sound level, motion, or light.

5. The method of claim 1, further comprising receiving a second energy data item and transmitting the second energy data item.

6. The method of claim 5, wherein the second energy data item includes data representing measured energy consumed by a second electrical device and an second identifier.

7. The method of claim 5, wherein the second energy data item includes data representing measured energy consumed from a second energy source and a second identifier.

8. An apparatus comprising:
a measurement module to create local energy consumption data by measuring energy consumption of an electrical device;
a storage module to store the measured local energy consumption data;
a receiver to receive non-local energy consumption data; and
a transmitter to transmit the local energy consumption data and the non-local energy consumption data.

9. The apparatus of claim 8, wherein the transmitter transmits the local energy consumption data and the non-local energy consumption data as broadcast transmissions.

10. The apparatus of claim 8, wherein the measurement module includes an identification.

11. The apparatus of claim 10, wherein the identification of the measurement module is included in the local energy consumption data.

12. The apparatus of claim 10, further comprising a visual indicator to indicate at least one of the following: operational status or energy consumption.

13. An electrical device comprising:
one or more electrical components configured to be connected to a source of electricity;
a measurement module to measure the electrical energy use by the one or more electrical components to create energy usage data by integrating a measurement of electrical energy over time;
a memory to store the energy usage data; and
a radio to transmit the energy usage data.

14. The electrical device of claim 13, wherein the energy usage data is measured in one of the following: Watt-hours or Joules.

15. The electrical device of claim 13, wherein the measurement of electrical energy is determined by multiplying a measured voltage by a measured current.

16. The electrical device of claim 13, wherein the energy usage data further includes at least one of the following: over-voltage data, under-voltage data, average voltage, average current, peak voltage, peak current, peak power, or bottom power.

17. An electrical cable comprising:
a first connector to be connected to an electrical device;
a second connector to be connected to an electricity source;
a measurement module to measure the electrical energy use by the electrical device from the electricity source to create energy usage data;
a memory to store the energy usage data; and
a radio to transmit the energy usage data.

18. The electrical cable of claim 17, wherein the radio is further operable to receive energy usage data transmissions.

19. The electrical cable of claim 17, further comprising a computer readable identifier, the identifier being associated with the energy usage data.

20. The electrical cable of claim 19, wherein the identifier is visibly positioned between the first connector and the second connector.
